(19) United States
(12) Patent Application Publication
(10) Pub. No.: US 2026/0344444 A1
(43) Pub. Date: Oct. 29, 2026

(54) SEMICONDUCTOR PACKAGE INCLUDING WIRING SUBSTRATE SHIELD

(71) Applicant: Samsung Electronics Co., Ltd., Suwon-si (KR)

(72) Inventors: Seokbeom Yong, Suwon-si (KR); Eunkyeong Park, Suwon-si (KR); Sungoh Ahn, Suwon-si (KR); Seungsoo Ha, Suwon-si (KR)

(73) Assignee: Samsung Electronics Co., Ltd., Suwon-si (KR)

(21) Appl. No.: 19/441,255

(22) Filed: Jan. 6, 2026

(30) Foreign Application Priority Data
Apr. 29, 2025 (KR) 10-2025-0056397

(51) Int. Cl. H10W 42/20

(52) U.S. Cl. CPC H10W 42/276

(57) ABSTRACT

A semiconductor package includes a wiring substrate having wiring layers and a shield structure. The uppermost wiring layer in the wiring layers includes a first signal line and a second signal line spaced apart from one another along a first direction substantially parallel to the top surface of the wiring substrate, and a first ground line disposed between the first signal line and the second signal line. The shield structure includes shield vias on the first ground line, and a shield line on the shield vias. The shield line is disposed between the first signal line and the second signal line in a plan view.

### CROSS-REFERENCE TO RELATED APPLICATIONS

This present application claims priority to and the benefit under 35 U.S.C. § 119(a)-(d) of Korean Patent Application No. 10-2025-0056397, filed on Apr. 29, 2025, in the Korean Intellectual Property Office, the entire disclosure of which is incorporated herein by reference.

### FIELD

The disclosed concepts relate to a semiconductor package and more particularly to a semiconductor package having a wiring substrate shield, and method of manufacturing the same.

### BACKGROUND

Semiconductor packages implement integrated circuit chips in a form suitable for use in electronics. Typically, it is common for semiconductor packages to mount semiconductor chips on printed circuit boards and electrically connect them using bonding wires or bumps. With the development of the electronics industry, various studies have been conducted to improve the reliability and downsizing of semiconductor packages.

### SUMMARY

Disclosed concepts of the embodiments are to improve the signal quality of a wiring substrate of a semiconductor package and to increase the reliability of the semiconductor package.

The disclosed concepts are not limited to the problem mentioned above, and other problems not mentioned may be clearly understood by those skilled in the art from the following description.

A semiconductor package according to some embodiments may comprise a wiring substrate comprising wiring layers and a shield structure, an uppermost wiring layer of the wiring layers may comprise a first signal line and a second signal line spaced apart along a first direction substantially parallel to a top surface of the wiring substrate, and a first ground line disposed between the first signal line and the second signal line, the shield structure may comprise shield vias on the first ground line and a shield line on the shield vias, and the shield line may be disposed between the first and second signal lines in a plan view.

A semiconductor package according to some embodiments may comprise a wiring substrate comprising wiring layers, a shield structure, and a bump pad, and a semiconductor chip on the wiring substrate, an uppermost wiring layer in the wiring layers may comprise a first signal line and a second signal line spaced apart along a first direction substantially parallel to a top surface of the wiring substrate, and a ground line disposed between the first signal line and the second signal line, the bump pad and the shield structure may be disposed on the uppermost wiring layer, the shield structure may comprise shield vias on the ground line and a shield line on the shield vias, the semiconductor chip may comprise a chip pad and a connection terminal interposed between the chip pad and the bump pad, and the shield line may be located at a same level as a level of the bump pad.

A semiconductor package according to some embodiments may comprise a first semiconductor package, the first semiconductor package comprises a first wiring substrate comprising a first surface and a second surface opposite one another, a semiconductor chip on the first surface of the first wiring substrate, and first connection terminals on the second surface of the first wire substrate, at least some of the first connection terminals may be non-overlapping with the semiconductor chip, the semiconductor chip may comprise a chip pad and a second connection terminal on the chip pad, the second connection terminal may be disposed between the chip pad and the first wiring substrate, the first wiring substrate may comprise wiring layers and a shield structure, the wiring layers may comprise a first wiring layer and a second wiring layer disposed below the first wiring layer, the first wiring layer located at an uppermost one of the wiring layers may comprise a first signal line, a second signal line which are spaced apart from one another along a first direction substantially parallel to a top surface of the first wiring substrate, and a ground line disposed between the first signal line and the second signal line, a second wiring layer may comprise a ground plane overlapping with the first signal line, the second signal line and the ground line, and the shield structure may comprise shield vias on the ground line and a shield line on the shield vias.

### BRIEF DESCRIPTION OF THE DRAWINGS

Example embodiments will be more clearly understood from the following brief description with the accompanying drawings. The accompanying drawings represent non-limiting, example embodiments as described herein.

FIG. 1 is a plan view of a semiconductor package according to some embodiments.

FIG. 2 is an enlarged view of UU1 of FIG. 1.

FIG. 3 is a cross-sectional view according to I-I of FIG. 2.

FIG. 4 is a perspective view conceptually illustrating FIG. 2.

FIG. 5 is a cross-sectional view of a wiring substrate according to some embodiments.

FIG. 6 is a cross-sectional view of A-A′ of FIG. 1.

FIG. 7 is an enlarged view of UU2 of FIG. 6.

FIG. 8 is a cross-sectional view of B-B′ of FIG. 1.

FIG. 9 is a diagram conceptually illustrating a signal interference shielding effect of a wiring substrate.

FIG. 10 is a diagram conceptually illustrating a signal interference shielding effect of a wiring substrate.

FIG. 11 is a cross-sectional view of a semiconductor package according to some embodiments.

FIG. 12 is a cross-sectional view of a semiconductor package according to some embodiments.

FIG. 13 is a plan view of a semiconductor package according to some embodiments.

FIG. 14 is a cross-sectional view of a semiconductor package according to some embodiments.

FIGS. 15A, 15B, 16, 17A, 17B, 18A, and 18B are cross-sectional views illustrating a manufacturing process of a semiconductor package according to some embodiments.

### DETAILED DESCRIPTION

Hereinafter, a semiconductor package according to the inventive concept will be described with reference to the drawings.

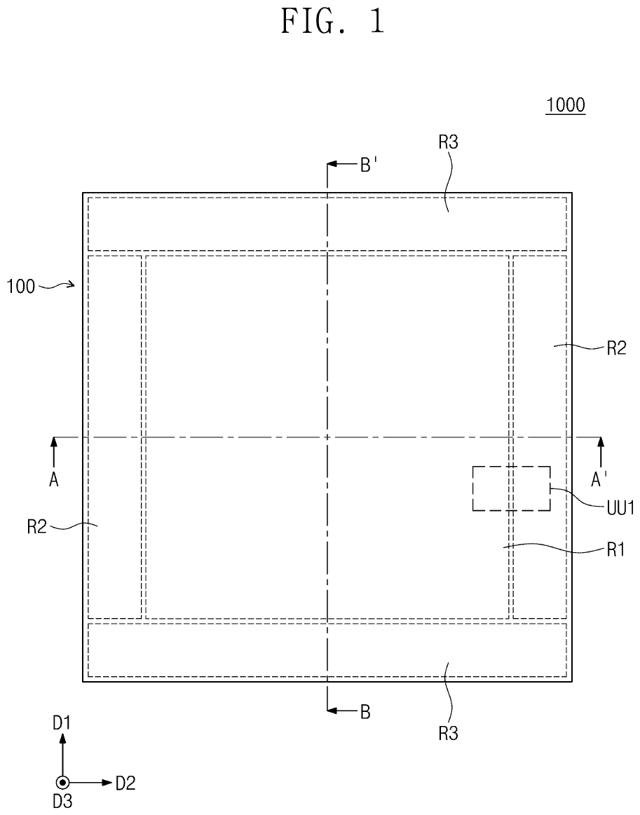

FIG. 1 is a top view of a semiconductor package according to some embodiments.

Referring to FIG. 1, a semiconductor package 1000 may include a wiring substrate 100.

In the present specification, a first direction D1, a second direction D2, and a third direction D3 may be directions perpendicular to one another. The first direction D1 and the second direction D2 may be directions parallel to the top surface of the wiring substrate 100. The third direction D3 may be a direction perpendicular to the top surface of the wiring substrate 100. In the present specification, a horizontal direction means the first direction D1 and/or the second direction D2. A vertical direction means the third direction D3.

The wiring substrate 100 may be a substrate on which a semiconductor chip is mounted. The wiring substrate 100 may be, for example, a redistribution substrate. The wiring substrate 100 may include a first region R1, a second region R2 surrounding the first region R1, and a third region R3. The first region R1 may be a region on which a semiconductor chip is mounted. The first region R1 may be a region where the semiconductor chip and the wiring substrate 100 overlap with one another in the third direction D3. The first region R1 may be a region in which a ground line, a ground plane, a power line, and a power plane are disposed. One end of the signal line may start from an edge of the first region R1 and extend out of the first region R1. The plane is a continuous metal layer structure disposed in a wiring layer, and for example, may have a plate shape. The plane refers to a structure that performs functions such as power supply, grounding, and electromagnetic interference shielding. The second region R2 may be provided in plural. The plurality of second regions R2, for example, may be disposed to be spaced apart from one another in the second direction D2 with the first region R1 interposed therebetween. The second region R2 may be a region in which the other end of the signal line, a ground line and a ground plane are disposed. For example, the third region R3 may be provided in plural. The plurality of third regions R3 may be disposed to be spaced apart from one another in the first direction D1 with the first region R1 interposed therebetween. The third region R3 may be a region in which the metal post structure is disposed. The metal post structure may electrically connect the wiring substrate 100 and the upper wiring substrate disposed on the wiring substrate 100. The third region R3 may be a region in which a power line and a ground line are disposed. According to some embodiments, the third region R3 may further include a power plane.

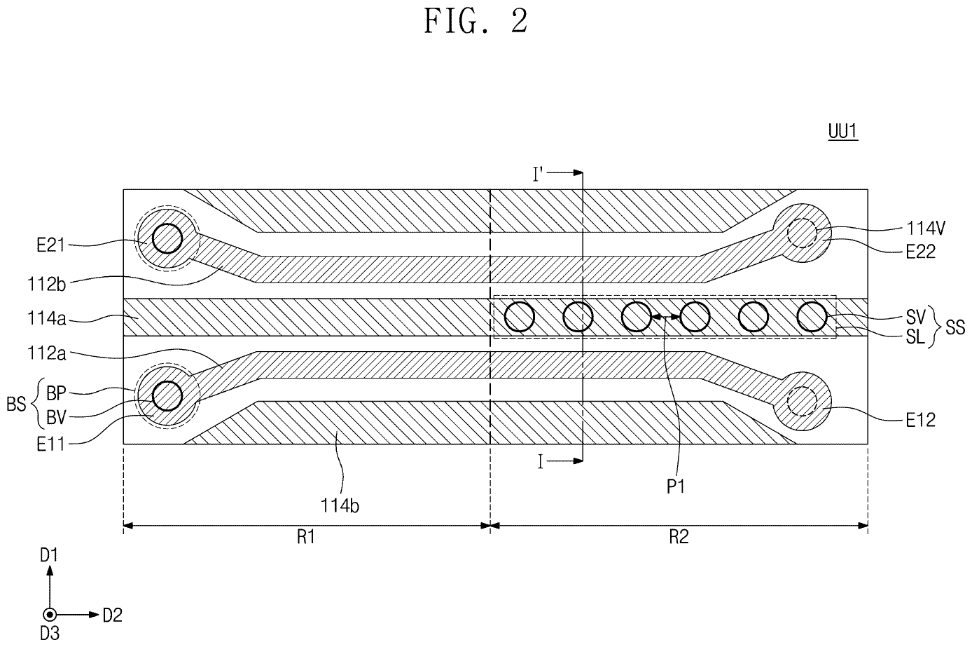

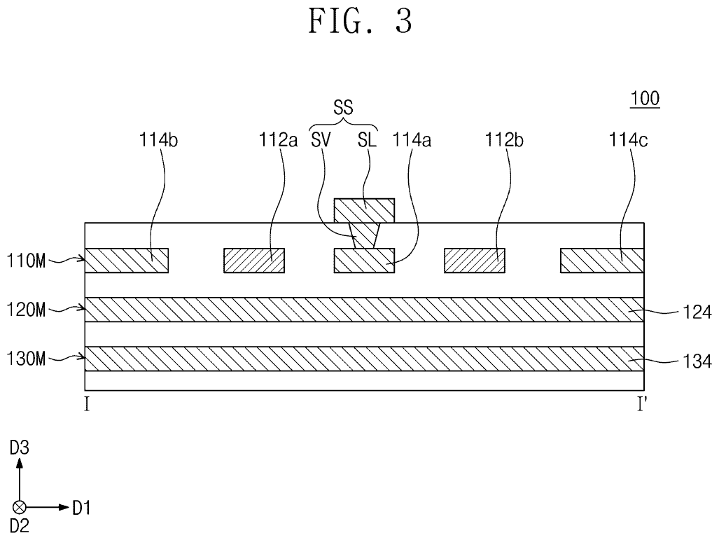

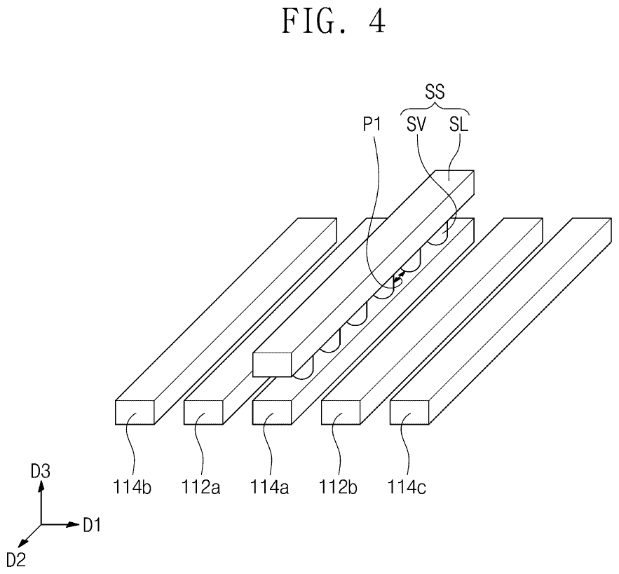

FIG. 2 is an enlarged view of UU1 of FIG. 1. Specifically, FIG. 2 is a plan view showing wirings disposed on an uppermost wiring layer of the first region R1 and the second region R2 of the wiring substrate. FIG. 3 is a cross-sectional view according to I-I of FIG. 2. FIG. 4 is a perspective view conceptually illustrating FIG. 2.

Referring to FIGS. 2, 3, and 4, the wiring substrate 100 may include wiring layers 110M, 120M, and 130M stacked in the third direction D3. The wiring layers 110M, 120M, and 130M may include a first wiring layer 110M, a second wiring layer 120M, and a third wiring layer 130M. For example, the first wiring layer 110M may be an uppermost wiring layer, and the third wiring layer 130M may be a lowermost wiring layer 130M. The number of wiring layers may be adjusted depending on the purpose or design requirements of the semiconductor package.

Each of the first wiring layer 110M, the second wiring layer 120M, and the third wiring layer 130M may include a signal line, a power line, a power plane, a ground line, and a ground plane. The first wiring layer 110M may include a first signal line 112a, a second signal line 112b, a first ground line 114a, a second ground line 114b, and a third ground line 114c disposed at an edge of the first region R1 and the second region R2.

One end E11 of the first signal line 112a and one end E21 of the second signal line 112b may be located in the first region R1. The first signal line 112a and the second signal line 112b may extend in the second direction D2. The other end E12 of the first signal line 112a and the other end E22 of the second signal line 112b may be located in the second region R2. The first signal line 112a and the second signal line 112b may be disposed to be spaced apart from one another in the first direction D1. The first ground line 114a may be disposed between the first signal line 112a and the second signal line 112b. The second ground line 114b may be disposed to be spaced apart from the first ground line 114a in the first direction D1 with the first signal line 112a interposed therebetween. The third ground line 114c may be disposed to be spaced apart from the first ground line 114a in the first direction D1 with the second signal line 112b interposed therebetween. According to some embodiments, a ground plane may be disposed in place of the second ground line 114b and the third ground line 114c.

A shield structure SS may be disposed on the first ground line 114a. The shield structure SS may include a shield line SL and shield vias SV. The shield line SL may have the shape of a line. The shield line SL may be referred to herein as a metal line pattern SL. The shield line SL may be disposed outside the first region R1 and may be disposed in the second region R2. The shield line SL may extend from a boundary between the first region R1 and the second region R2 to a region between the respective other ends E12, E22 of the first signal line 112a and the second signal line 112b in the second region R2, or beyond. According to some embodiments, the shield line SL may extend to a corner of the wiring substrate 100. The shield line SL may overlap the first ground line 114a in the third direction D3. In a plan view, the shield line SL may be disposed between the first signal line 112a and the second signal line 112b. The shield line SL may be spaced apart from the first signal line 112a and the second signal line 112b in the first direction D1 in a plan view.

The shield vias SV may be disposed between the first ground line 114a and the shield line SL. The shield vias SV may be spaced apart from one another at a first constant interval P1 along the shield line SL. For example, the first spacing P1 may be greater than 0 and 500 μm. For example, the first spacing P1 may be greater than 50 μm and 500 μm. For example, the first spacing P1 may be 200 μm. The shield line SL may be electrically connected to the first ground line 114a through the shield vias SV.

The bump pad structure BS may be disposed on one end E11 and one end E21 of each of the first signal line 112a and the second signal line 112b located in the first region R1. The bump pad structure BS may include a bump pad BP and a bump pad via BV. The bump pad via BV may be disposed between the bump pad BP and each of the one ends E11, E21 of the first and second signal lines 112a, 112b. The bump pad BP may be electrically connected to the first signal line 112a and the second signal line 112b through the bump pad via BV.

A first via 114V may be disposed below each of the other ends E12, E22 of the first signal line 112a and the second signal line 112b located in the second region R2. Each of the first signal line 112a and the second signal line 112b may be electrically connected to the signal lines of the second wiring layer 120M through the first via 114V.

The second wiring layer 120M may include a first ground plane 124 overlapping the first signal line 112a, the second signal line 112b, and the first ground line 114a in the third direction D3. A width of the shield line SL in the first direction D1 may be smaller than that of the first ground plane 124 in the first direction D1. The third wiring layer 130M may include a first signal line 112a, a second signal line 112b, and a second ground plane 134 overlapping the first ground line 114a in the third direction D3. According to some embodiments, the second ground plane 134 may be omitted, and signal wires and ground lines may be disposed.

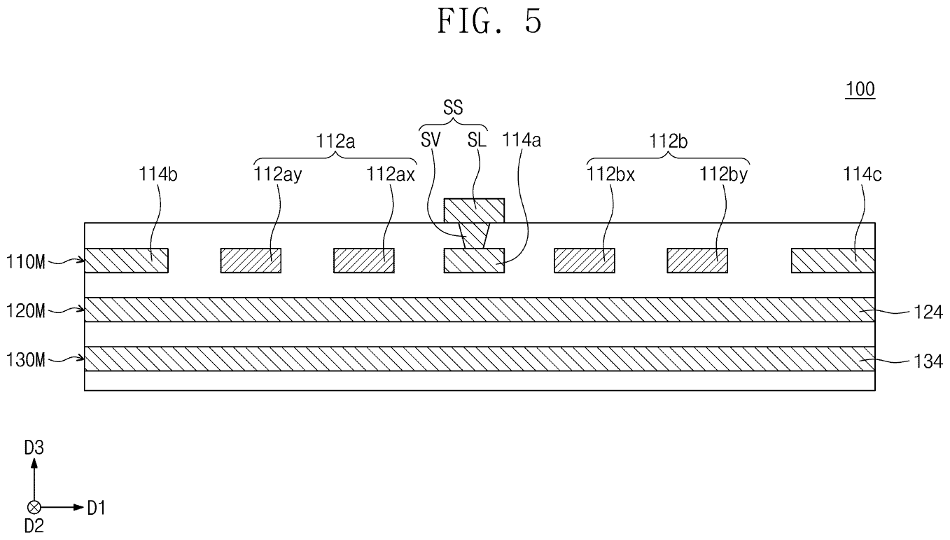

FIG. 5 is a cross-sectional view of a wiring substrate according to some embodiments.

Referring to FIG. 5, a pair of first signal lines 112a and a pair of second signal lines 112b may be provided. Specifically, the first signal line 112a may include a first sub signal line 112ax and a second sub signal line 112ay. The second signal line 112b may include a third sub signal line 112bx and a fourth sub signal line 112by. The first sub signal line 112ax and the second sub signal line 112ay may transmit differential signals. The third sub signal line 112bx and the fourth sub signal line 112by may transmit differential signals. That is, the first sub signal line 112ax, the second sub signal line 112ay, the third sub signal line 112bx, and the fourth sub signal line 112by may form differential routing.

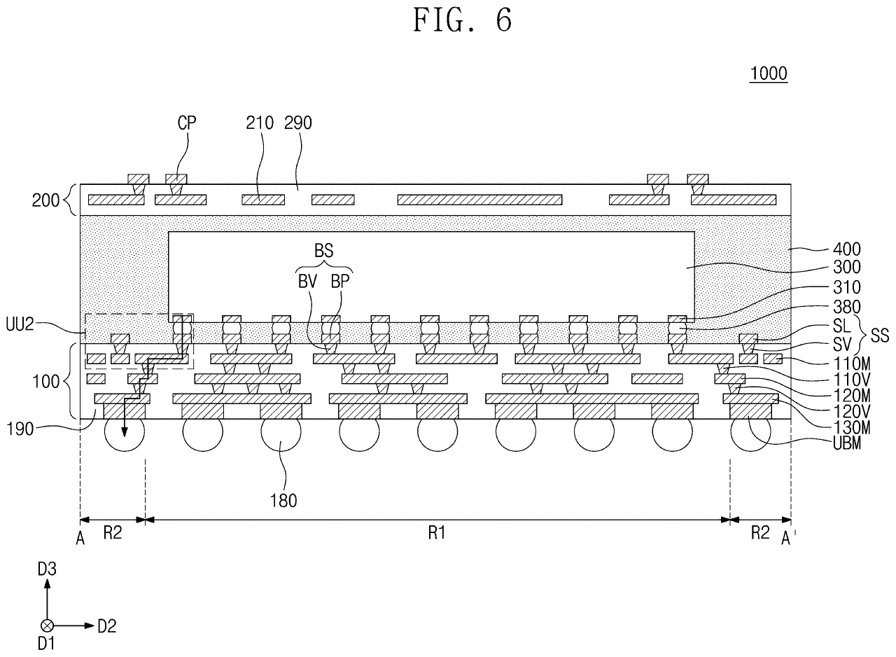

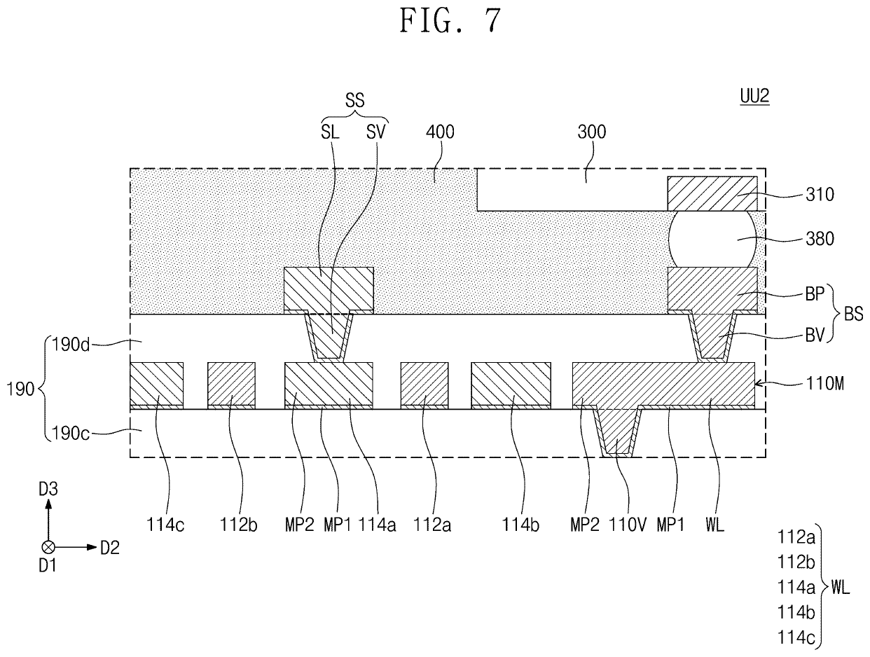

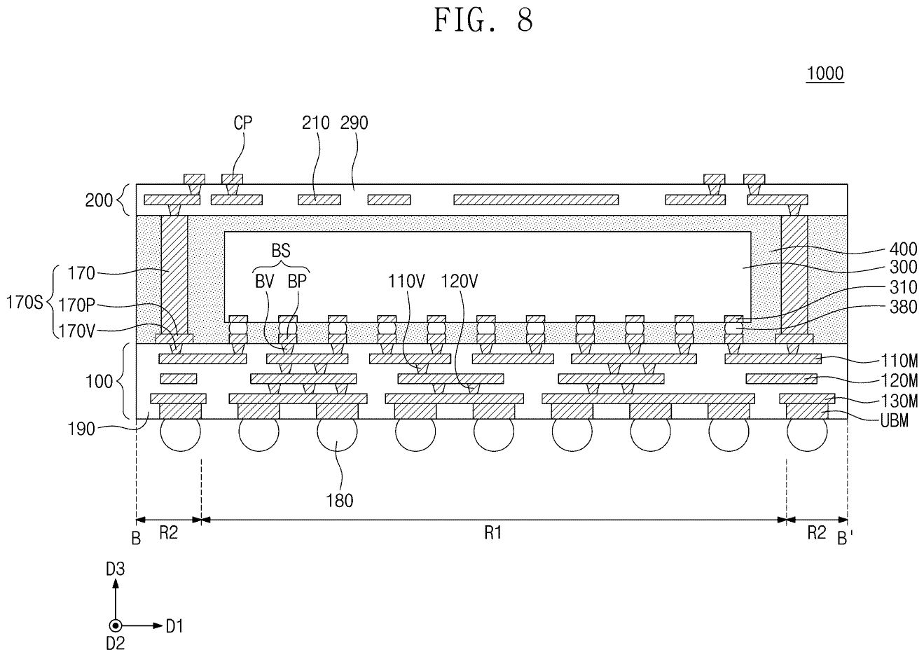

FIG. 6 is a cross-sectional view of A-A′ of FIG. 1. FIG. 7 is an enlarged view of UU2 of FIG. 6. FIG. 8 is a cross-sectional view of B-B′ of FIG. 1.

Referring to FIGS. 1 to 8, the wiring substrate 100 may further include a first via 110V, a second via 120V, an under-bump pattern UBM, a metal post structure 170S, an insulating layer 190, and an external connection terminal 180.

The first via 110V may be interposed between wirings and a plane of the first wiring layer 110M, and wirings and a plane of the second wiring layer 120M to electrically connect them. The second via 120V may be interposed between the wirings and the plane of the second wiring layer 120M, and the wirings and the plane of the third wiring layer 130M to electrically connect them. The under-bump patterns UBM may be disposed below the third wiring layer 130M. A via may not be interposed between the wirings and the plane of the third wiring layer 130M, and the under-bump patterns UBM. The external connection terminal 180 may be disposed on a bottom surface of each of the under-bump patterns UBM. The external connection terminal 180 may be disposed on the bottom surface of the wiring substrate 100. The external connection terminal 180 may be, for example, a solder balls. A portion of the external connection terminal 180 may be disposed on the second region R2 and the third region R3. That is, the portion of the external connection terminal 180 may be spaced apart from the semiconductor chip 300 in the diagonal direction and may be non-overlapped in the third direction D3. For example, the signal of the semiconductor chip 300 may be transmitted through the connection terminal 380, the signal lines of the wiring substrate 100, and the external connection terminal 180 disposed on the second region R2. That is, the semiconductor package 1000 may be a fan-out semiconductor package.

The metal post structure 170S may be disposed on the third region R3 of the wiring substrate 100. The metal post structure 170S may include a metal post 170, a post pad 170P, and a post pad via 170V. The metal post 170 may cross the mold layer 400 in the third direction D3 from the top surface of the wiring substrate 100. A post pad 170P may be disposed below the metal post 170, and a post pad via 170V may be disposed below post pad 170P.

The insulating layer 190 may cover top surfaces, bottom surfaces, and side surfaces of wirings and planes of the first to third wiring layers 110M, 120M, and 130M, side surfaces of the first and second vias 110V and 120V, a side surface of the bump pad via BV, a side surfaces of the shield via SV, a side surface of the under-bump pattern UBM, and a side surface of a post pad via 170V. Top and side surfaces of the bump pad BP, and top and side surfaces of a shield line SL, and a side surface of the post pad 170P may be exposed from the insulating layer 190. The insulating layer 190 may be formed from a photo-imageable dielectric material. The insulating layer 190 may include, for example, a polymer material. The photo-imageable dielectric material may include, for example polyimide, polybenzoxazole (PBO), or benzocyclobutene (BCB). The insulating layer 190 is denoted as one insulating layer, but may actually include stacked insulating layers.

As shown in FIG. 7, each of a wiring WL, the plane, the shield structure SS, the bump pad structure BS, and the metal post structure 170S may include a seed pattern MP1 and a conductive pattern MP2. The conductive pattern MP2 may be disposed on the seed pattern MP1. The seed pattern MP1 may include, for example, at least one of copper, chromium, titanium, or titanium/tungsten. The conductive pattern MP2 may include, for example, copper.

The semiconductor chip 300 may be mounted on the first region R1 of the wiring substrate 100. The semiconductor chip 300 may be disposed on the top surface of the wiring substrate 100. A chip pad 310 may be disposed on a bottom surface of the semiconductor chip 300. A connection terminal 380 may be disposed between the chip pad 310 and the bump pad BP. The connection terminal 380 may be, for example, a bump. The connection terminal 380 may not be disposed on the shield line SL.

A mold layer 400 may be disposed on the wiring substrate 100. The mold layer 400 may be formed, for example, from an epoxy molding compound. The mold layer 400 may cover a side surface and a top surface of the semiconductor chip 300 and a top surface the wiring substrate 100. The mold layer 400 may fill between the connection terminals 380. The top surface and the side surface of the shield line SL may be in contact with the mold layer 400.

According to some embodiments, the semiconductor package 1000 may further include an underfill. The underfill may fill a gap between the bottom surface of the semiconductor chip 300 and the top surface of the wiring substrate 100.

The bump pad BP and the shield line SL may be disposed at the same level. The post pad 170P may be disposed at the same level as the bump pad BP and the shield line SL.

The semiconductor package 1000 may further include a second wiring substrate 200 spaced apart from the wiring substrate 100 in the third direction D3. The wiring substrate 100 may be referred to as a first wiring substrate 100. The second wiring substrate 200 may be, for example, a redistribution substrate. The second wiring substrate 200 may include a second insulating layer 290 and at least one upper wiring layer 210 disposed in the second insulating layer 290, the upper wiring layer including wirings, planes, and vias. The insulating layer 190 may be referred to as a first insulating layer 190. The second insulating layer 290 may be formed from a photosensitive insulating material and may include substantially the same material as the first insulating layer 190. Wirings, planes, and vias of the upper wiring layer 210 may include metal (i.e., copper). The second wiring substrate 200 may further include a connection pad CP electrically connected to the wirings and the plane of the upper wiring layer 210.

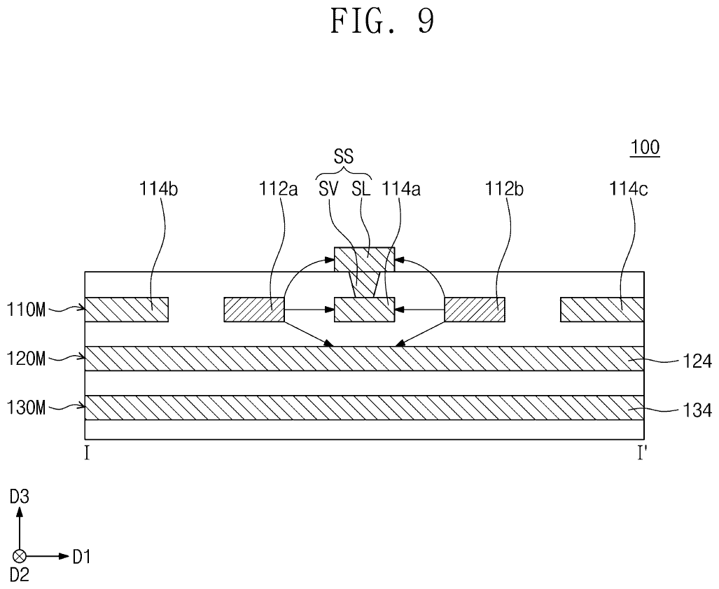

FIG. 9 is a diagram conceptually illustrating a signal interference shielding effect of a wiring substrate. Specifically, FIG. 9 illustrates a signal interference shielding effect of the wiring substrate 100 according to the embodiments of FIG. 3, and arrows indicate signal interference. Referring to FIG. 9, the first signal line 112a and the second signal line 112b adjacent to one another may transmit signals independently of one another, and signal interference may occur in this process. A first ground line 114a is disposed between the first signal line 112a and the second signal line 112b, and a first ground plane 124 is disposed below the first signal line 112a, the second signal line 112b, and the first ground line 114a, so that signal interference may be prevented.

According to one concept of the present invention, the shield structure SS is disposed on the first ground line 114a, and the shield structure SS is electrically connected to the first ground line 114a, so that signal interference may be effectively blocked. Specifically, signal interference crossing over the first ground line 114a may be blocked. In addition, the shield line SL may be disposed between the first signal line 112a and the second signal line 112b from a plan view, and may not cover the first signal line 112a and the second signal line 112b. The shield line SL has a line shape and may have a shape different from that of the plane. When the shield line SL has a planar shape and covers both the first signal line 112a and the second signal line 112b (stripline case), the signal impedance value may be lowered. That is, the width and shape of the shield line SL may improve signal quality such as signal integrity of the semiconductor package. In addition, when the shield line SL has a line shape, the reliability of the wiring substrate 100 may be improved in terms of degassing and warpage by preventing a significant increase in metal portions at the edge of the wiring substrate. For these reasons, the reliability of the semiconductor package may increase.

According to another inventive concept, the shield line SL may extend to the other ends E12 and E22 of the first signal line 112a and the second signal line 112b in a region between the first signal line 112a and the second signal line 112b disposed in the second region R2. This may effectively prevent signal interference as compared to forming a shield line only in a part of a region between the first signal line 112a and the second signal line 112b. In addition, as shield vias SV are provided at regular intervals, the ground function may be effectively performed.

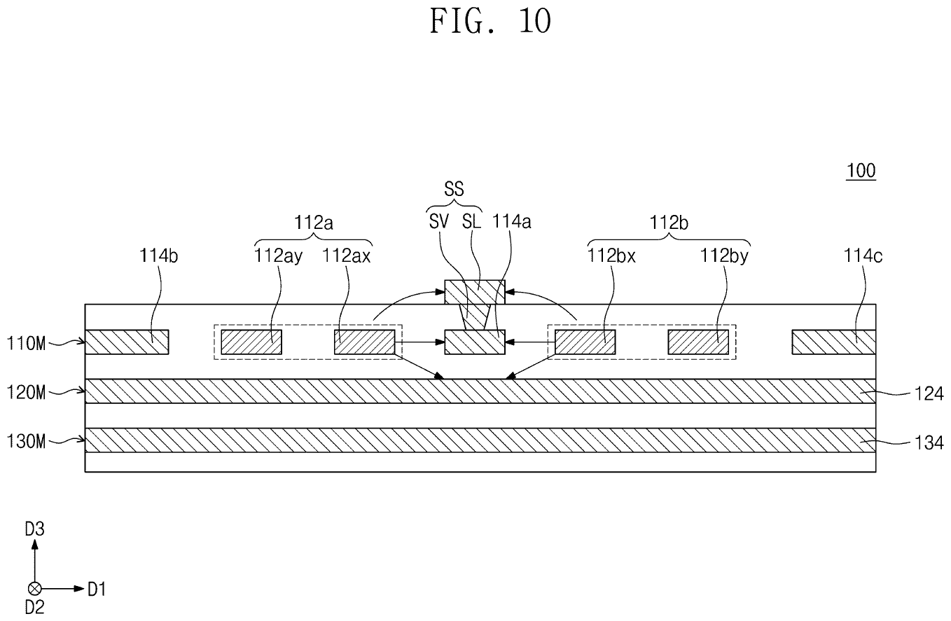

FIG. 10 is a diagram conceptually illustrating a signal interference shielding effect of a wiring substrate. FIG. 10 illustrates a signal interference shielding effect of the wiring substrate 100 according to the embodiments of FIG. 5, and arrows indicate signal interference. As shown in FIG. 10, the signal interference shielding effect can be equally applied even in cases where the first signal line 112a includes a pair of sub signal lines 112ax and 112ay and the second signal line 112b includes a pair of the sub signal line 112bx and 112by.

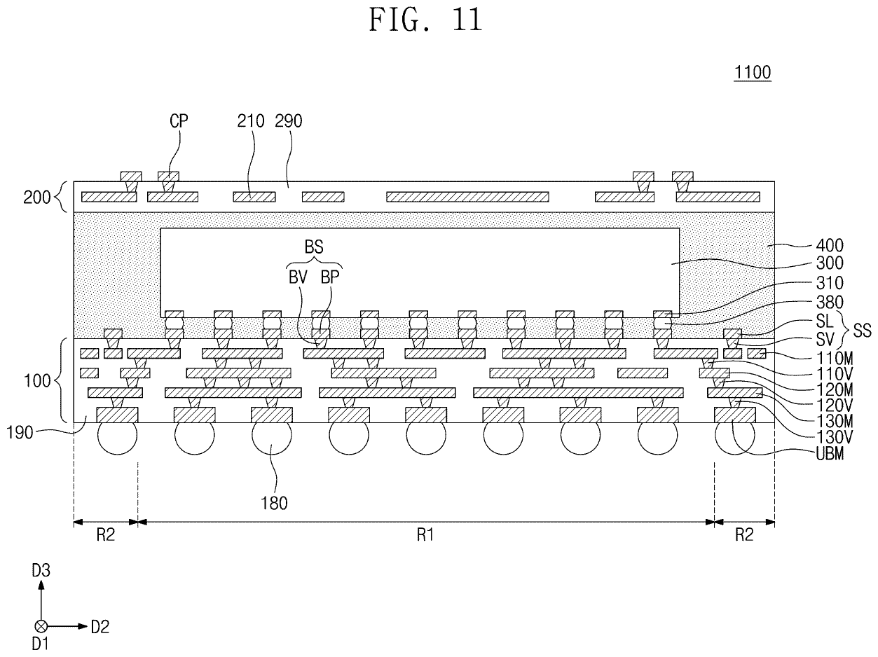

FIG. 11 is a cross-sectional view of a semiconductor package according to some embodiments. Referring to FIG. 11, the wiring substrate 100 may further include a third via 130V. The third via 130V may be disposed between the wirings and the plane of the third wiring layer 130M, and the under-bump pattern UBM. The third via 130V may electrically connect the wirings and the plane of the third wiring layer 130M to the under-bump pattern UBM.

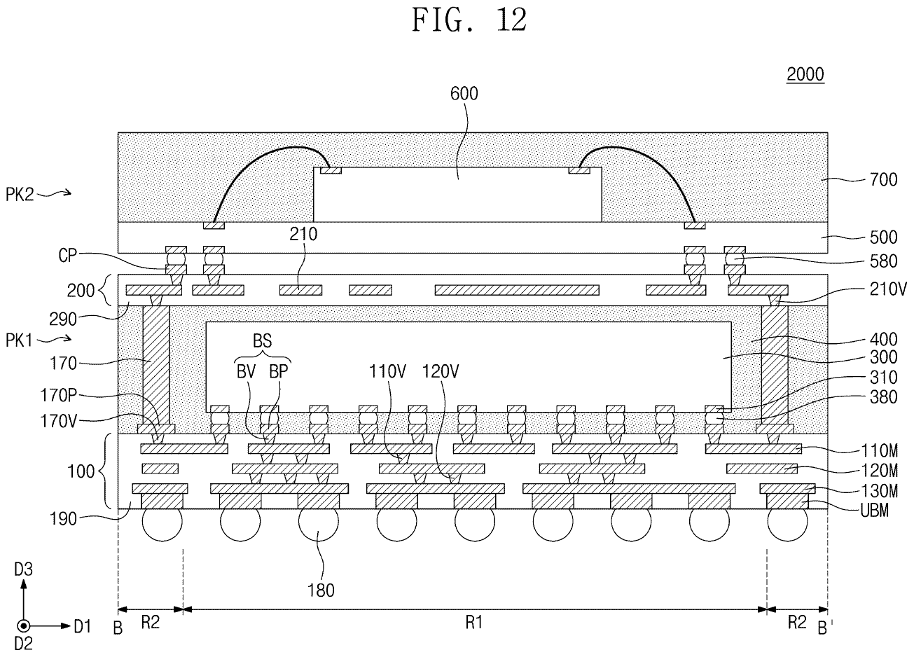

FIG. 12 is a cross-sectional view of a semiconductor package according to some embodiments.

Referring to FIG. 12, a semiconductor package 2000 according to some embodiments may further include a second semiconductor package PK2. The semiconductor package 1000 described above is referred to as a first semiconductor package PK1.

A second semiconductor package PK2 may be disposed on the first semiconductor package PK1. The second semiconductor package PK2 may include a package substrate 500, a second semiconductor chip 600, a second mold layer 700, and an internal connection terminal 580. Previously, the semiconductor chip 300 of the first semiconductor package PK1 may be referred to as a first semiconductor chip 300, and the mold layer 400 may be referred to a first mold layer 400.

The package substrate 500 may be, for example, a printed circuit board. The second semiconductor chip 600 may be a semiconductor chip that performs a function different from that of the first semiconductor chip 300. For example, the first semiconductor chip 300 may be a logic chip and the second semiconductor chip 600 may be a memory chip. For example, the first semiconductor chip 300 may be an application processor (AP), and the second semiconductor chip 600 may be a DRAM.

The second semiconductor chip 600 may be electrically connected to the package substrate 500 by a wire bonding. According to some embodiments, the second semiconductor chip 600 may be electrically connected to the package substrate 500 through flip chip bonding. The internal connection terminal 580 may be disposed below the package substrate 500. The internal connection terminal 580 may be, for example, a bump or a solder ball. The internal connection terminal 580 may be disposed on the connection pad CP. The second semiconductor package PK2 may be electrically connected to the first semiconductor package PK1 through the internal connection terminal 580. The second mold layer 700 may be formed from an epoxy molding compound. The second mold layer 700 may cover a top surface and a side surface of the second semiconductor chip 600 and a top surface of the package substrate 500.

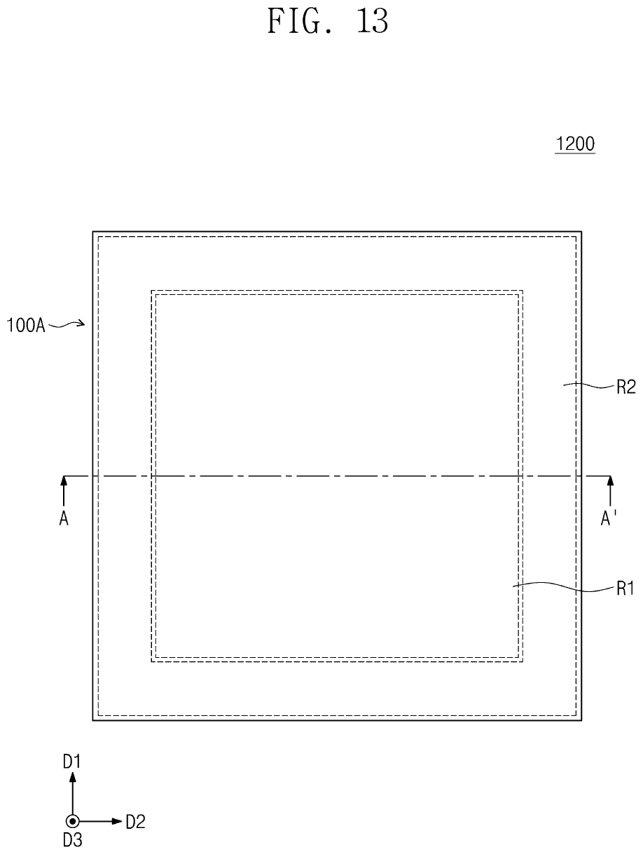

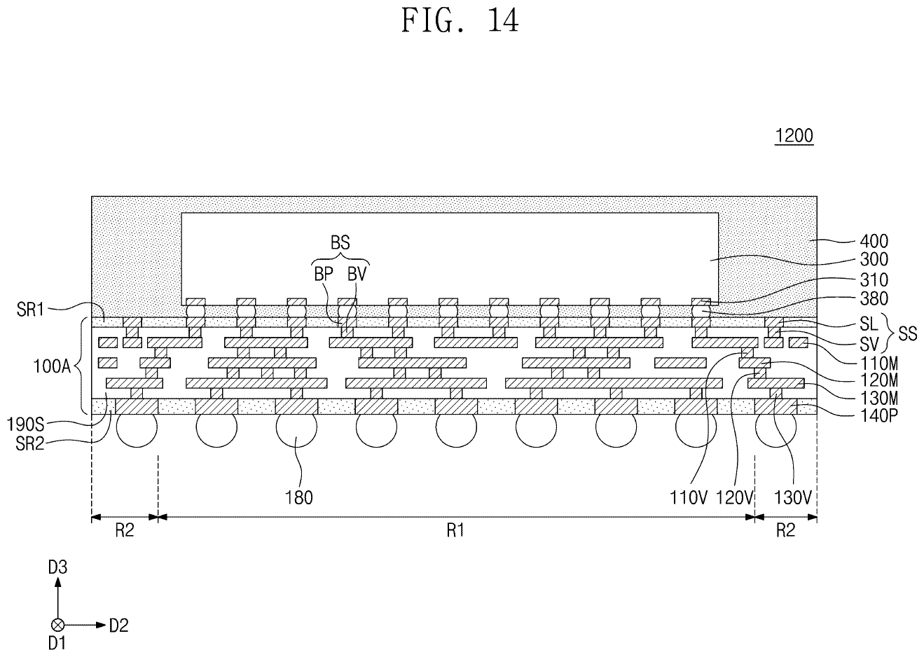

FIG. 13 is a plan view illustrating a semiconductor package according to some embodiments. FIG. 14 is a cross-sectional view according to A-A′ of FIG. 13.

Referring to FIGS. 13 and 14, a semiconductor package 1200 may include a third wiring substrate 100A. The semiconductor package 1200 may not include the second wiring substrate 200. The third wiring substrate 100A may be provided instead of the first wiring substrate 100. The third wiring substrate 100A may have characteristics similar to those of the first wiring substrate 100, except for the following configurations. That is, the third wiring substrate 100A may include features of the embodiments described with reference to FIGS. 2 to 5. The third wiring substrate 100A may be, for example, a printed circuit board. The third wiring substrate 100A may not include the third region R3 and the metal post structure 170S. That is, the second region R2 may surround the entire first region R1. The third wiring substrate 100A may include wiring layers 110M, 120M, 130M, vias 110V, 120V, 130V, a lower pad 140P, a bump pad structure BS, a shield structure SS, an insulating structure 190S, a first solder resist layer SR1, and a second solder resist layer SR2. The wiring layers 110M, 120M, 130M, the vias 110V, 120V, 130V the lower pad 140P, the bump pad structure BS, and the shield structure SS may include metal, for example, copper. The insulating structure 190S may include insulating materials such as prepreg, FR-4, polyimide, or resin-based core, which generally comprise epoxy resin and glass fiber. The third via 130V may be interposed between the wirings of the third wiring layer 130M and the lower pad 140P. A side surface of the bump pad BP and a side surface of the shield line SL may be covered by the first solder resist layer SR1. A side surface of the lower pad 140P may be covered by the second solder resist layer SR2. An external connection terminal 180 may be disposed on the lower pad 140P.

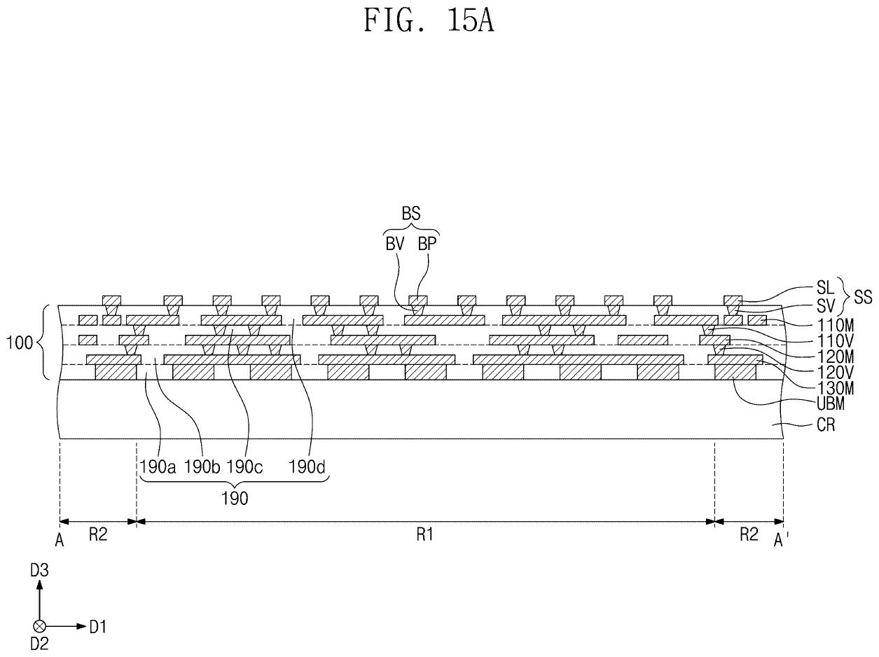

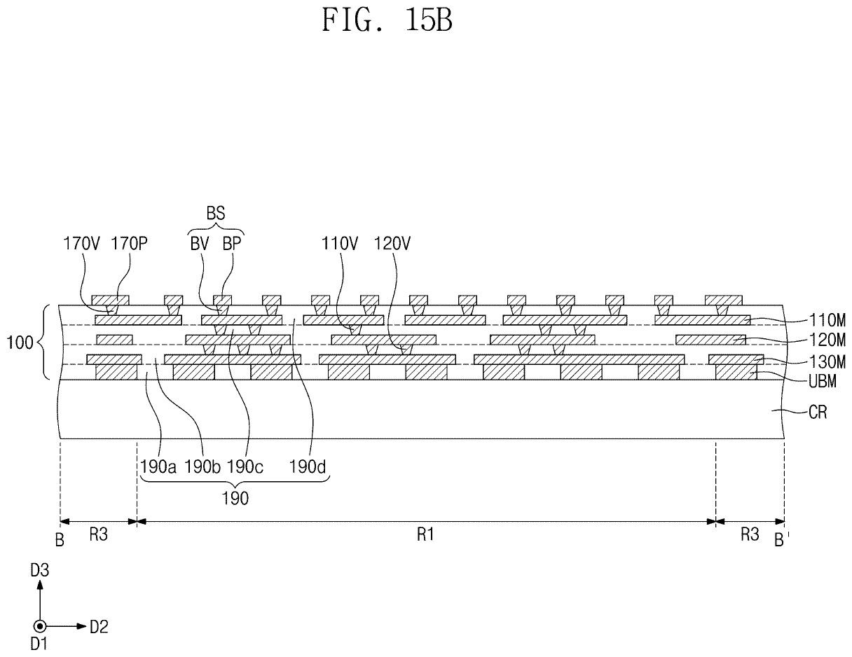

FIGS. 15A, 15B, 16, 17A, 17B, 18A, and 18B are cross-sectional views illustrating a manufacturing process of a semiconductor package according to some embodiments. FIGS. 15A, 17A, and 18A may correspond to A-A′ of FIG. 1. FIGS. 15B, 16, 17B, and 18B may correspond to B-B′ of FIG. 1.

Referring to FIGS. 15A and 15B, a carrier substrate CR may be provided. The carrier substrate CR may be, for example, a glass substrate or a silicon substrate. A metal thin film may be formed on the carrier substrate CR. The metal thin film may be, for example, a copper foil. The metal thin film may be formed through lamination or deposition. An adhesive layer may be formed on the carrier substrate CR before forming the metal thin film.

A first photomask pattern may be formed on a top surface of the metal thin film. The first photomask pattern may include a first opening defining a space in which the under-bump pattern UBM is to be formed. The first photomask pattern may be formed through a process of forming, exposing, and developing a photoresist layer. A portion of the top surface of the metal thin film may be exposed through the first opening. The under-bump pattern UBM may be formed by performing an electroplating process using a metal thin film as an electrode. The first photomask pattern may be removed. Then, a first sub insulating layer 190a covering a side surface of the under-bump pattern UBM may be formed. The first sub insulating layer 190a may be formed using a coating process such as spin coating, using a photosensitive insulating material. Next, the curing process of the first sub insulating layer 190a may proceed. A first seed layer may be formed on the first sub insulating layer 190a. A second photomask pattern may be formed on the first seed layer. The second photomask pattern may include a second opening defining a space in which wirings and planes of the third wiring layer 130M are to be formed. A conductive pattern MP2 (see FIG. 7) may be formed on the first seed layer in an electroplating process using the first seed layer as an electrode. The second photomask pattern may be removed. The exposed portion of the first seed layer may be etched to form a seed pattern MP1 (see FIG. 7) from the first seed layer. As a result, wirings and planes of the third wiring layer 130M may be formed.

According to some embodiments, when the first sub insulating layer 190a is formed, the first sub insulating layer 190a may further cover the top surface of the under-bump pattern UBM. The first sub insulating layer 190a may be patterned to have a third opening exposing at least a portion of the top surface of the under-bump pattern UBM. The third opening may define a space in which a third via 130V connected to a wiring or a plane of the third wiring layer 130M is to be formed (see FIG. 11).

A second sub insulating layer 190b covering top surfaces and side surfaces of the wirings and the plane of the third wiring layer 130M may be formed. The second sub insulating layer 190b may be formed through a coating process. Next, the second sub insulating layer 190b may be patterned to have a fourth opening that exposes the top surface of the wirings and the top surface of the plane of the third wiring layer 130M through an exposure process, a development process, and a curing process. The fourth opening may define a space in which a second via 120V connected to the wirings or the plane of the third wiring layer 130M is to be formed. A second seed layer may be formed on the second sub insulating layer 190b. A third photomask pattern may be formed on the second seed layer. The third photomask pattern may include a fifth opening defining a space in which the wirings and the plane of the second wiring layer 120M are to be formed. A conductive pattern may be formed on the second seed layer in an electroplating process using the second seed layer as an electrode. The third photomask pattern may be removed. The exposed portion of the second seed layer may be etched to form a seed pattern from the second seed layer. As a result, the wirings and the plane of the second wiring layer 120M and the second vias 120V may be formed.

The third sub insulating layer 190c, the wirings and the plane of the first wiring layer 110M, and the first vias 110V may be formed on the second wiring layer 120M in the same manner as in the method described above. In the process of forming the wirings of the first wiring layer 110M, the first and second signal lines 112a, 112b and the first ground line 114a disposed therebetween, which are described with reference to FIGS. 2 to 5, may be formed.

A fourth sub insulating layer 190d may be formed to cover top surfaces and side surfaces of the wirings and the plane of the first wiring layer 110M. The fourth sub insulating layer 190d may be patterned to have a sixth opening that exposes the wiring of the first wiring layer 110M and the top surface of the plane through an exposure process, a development process, and a curing process. The top surface of the fourth insulating layer is identified with the top surface of the first wiring substrate 100. A third seed layer may be formed on the fourth sub insulating layer 190d. A fourth photomask pattern including a first pad opening, a second pad opening, and a line opening may then be formed. The first pad opening defines a space in which the bump pad BP is to be formed. The second pad opening defines the space in which the post pad 170P is to be formed. The line opening may define a space in which a shield line SL is to be formed. The bump pad structure BS, the shield structure SS, the post pad via 170V, and the post pad 170P may be simultaneously formed in an electroplating process using the third seed layer as an electrode. The first to fourth sub insulating layers 190a to 190d may constitute the first insulating layer 190. The shield via SV may be formed directly on the first ground line 114a of the first wiring layer 110M. The shield via SV may be formed at the same level as the bump pad via BV and the post pad via 170V. The shield line SL may be formed at the same level as the bump pad BP and the post pad 170P.

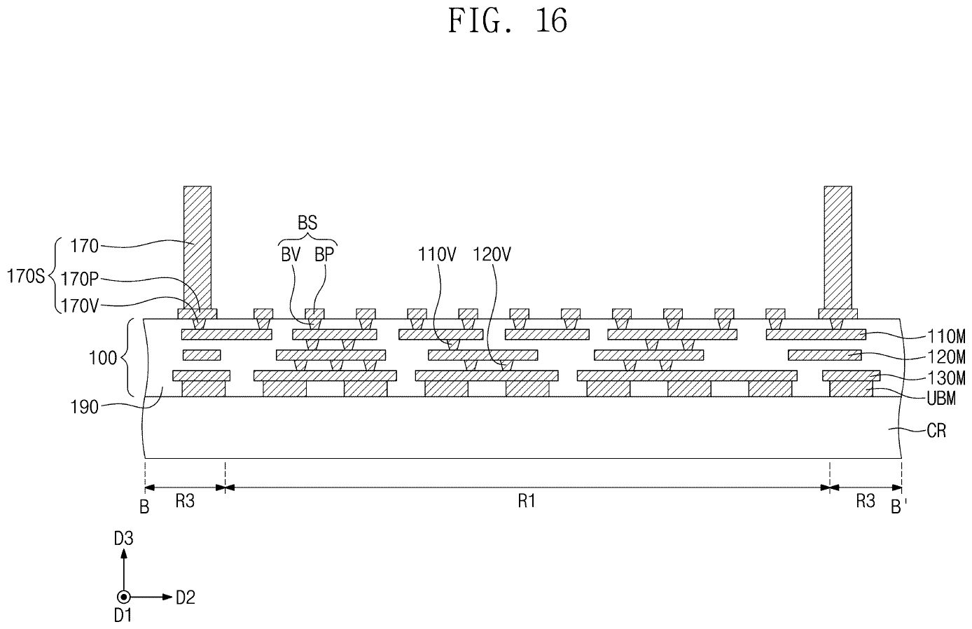

Referring to FIG. 16, a fifth photomask pattern may be formed on the top surface of the first wiring substrate 100. The fifth photo mask pattern may include a seventh opening that exposes at least a portion of the top surface of the post pad 170P and defines a space in which the metal post 170 is to be formed. The metal post may be formed in an electroplating process using the third seed layer as an electrode. The fifth photomask pattern may then be removed and the exposed portion of the third seed layer etched. As a result, a metal post structure 170S may be formed.

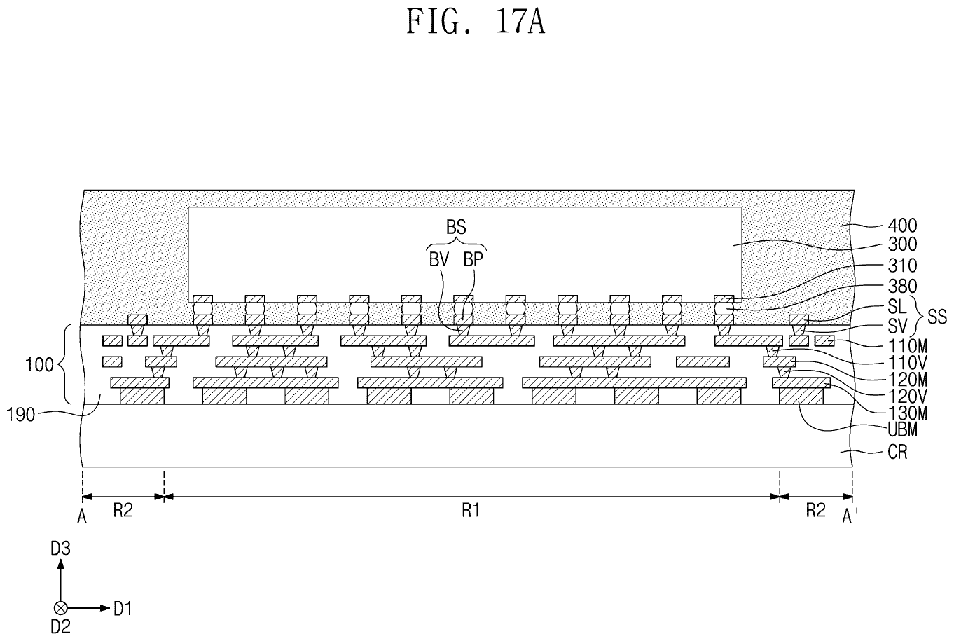

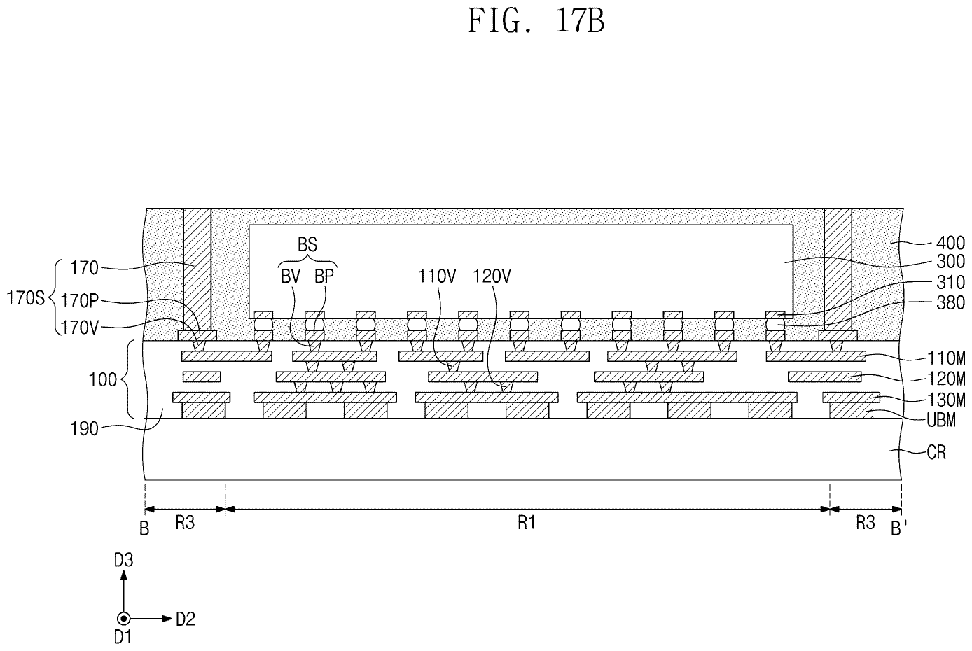

Referring to FIGS. 17A and 17B, the first semiconductor chip 300 may be mounted on the first region R1 of the first wiring substrate 100. Connection terminals 380 attached on chip pads 310 may be attached on bump pads BP, respectively. A mold layer 400 covering a top surface of the wiring substrate 100, a top surface and a side surface of the first semiconductor chip 300, and a top surface and the side surface of the metal post 170 may be formed. The mold layer 400 may be formed by dispensing and curing a flowable molding material. The molding material may be, for example, an epoxy molding compound (EMC). A planarization process may proceed on the mold layer 400. The planarization process may proceed until the top surface of the metal post 170 is exposed. As a result of the planarization process, the top surface of the mold layer 400 and the top surface of a metal post 170 may be coplanar.

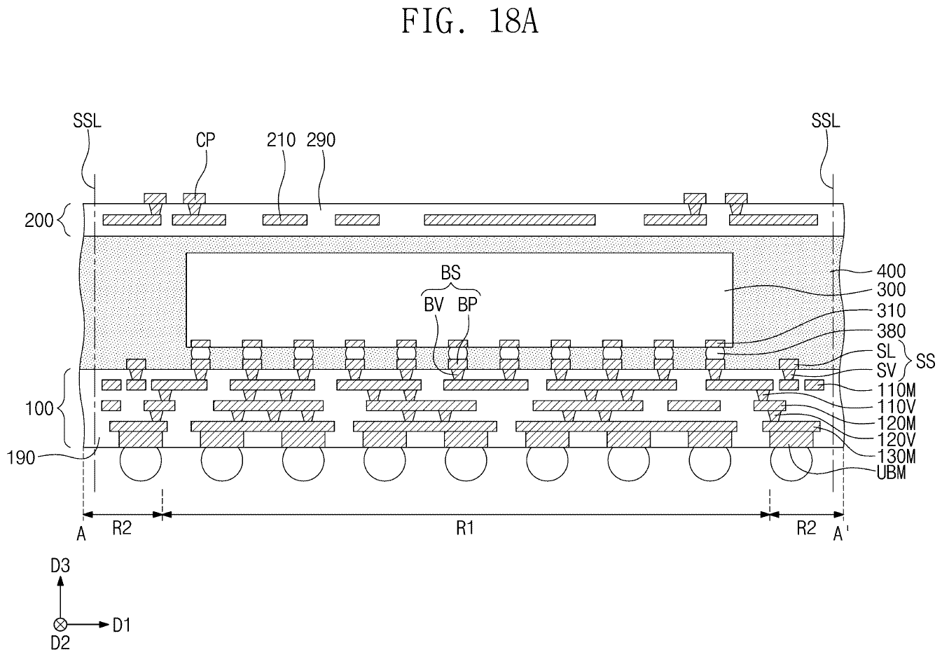

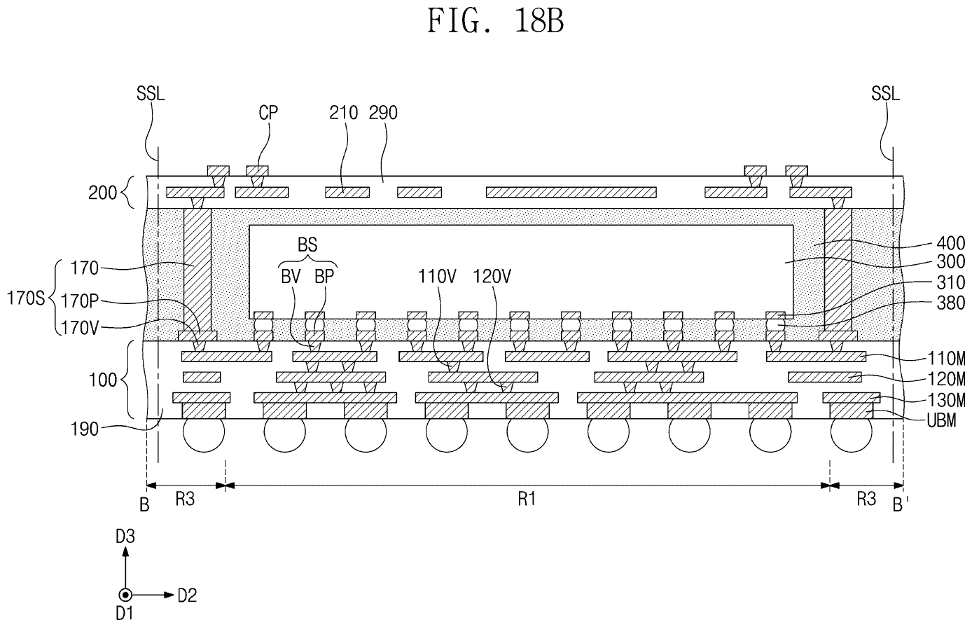

Referring to FIGS. 18A and 18B, a second wiring substrate 200 may be formed on the mold layer 400 and the metal post 170. The second wiring substrate 200 may be formed in substantially the same manner as or in a similar manner to the first wiring substrate 100. Wirings and planes of the upper wiring layer 210 of the second wiring substrate 200 may be formed to be electrically connected to the metal post 170.

The carrier substrate CR, the adhesive layer, and the metal thin film may then be removed. By removing the metal thin film, a bottom surface of the under-bump patterns UBM may be exposed. An external connection terminal 180 may be formed on the exposed under-bump patterns UBM. A singulation process may be performed along a sawing line SSL, and the semiconductor package 1000 of FIGS. 6 and 8 may be formed. Additionally, the second semiconductor package PK2 may be mounted on the semiconductor package 1000, and the semiconductor package 2000 of FIG. 12 may be formed.

According to the inventive concept, the semiconductor package may comprise a wiring substrate comprising a shield structure. The shield structure may include vias and a shield line, and may be disposed on a top surface of the wiring substrate. The shield structure may effectively shield signal interference between adjacent signal wires, thereby improving signal quality of the wiring substrate. As a result, the reliability of the semiconductor package may be increased.

A method of manufacturing a semiconductor package according to some embodiments may comprise forming a wiring substrate, forming the wiring substrate may comprise forming stacked wiring layers, and forming a bump pad structure and a shield structure on an uppermost wiring layer of the wiring layers, forming the uppermost wiring layer may comprise forming a first signal line and a second signal line spaced apart in a first direction, and a first ground line disposed therebetween, and forming the shield structure may comprise forming shield vias, and a shield line connected to the shield vias.

According to some embodiments, forming the wiring substrate may further comprise forming an under-bump pattern, and forming a lowermost wiring layer of the wiring layers on the under-bump pattern.

According to some embodiments, the lowermost wiring layer may comprise wirings and planes, and forming the lowermost wiring layer may comprise forming the wirings and the planes directly on the under-bump pattern.

According to some embodiments, the lowermost wiring layer may comprise wirings and planes, and may further comprise forming vias interposed between the wirings and the planes and the under-bump pattern.

According to some embodiments, forming the shield structure may comprise forming a seed pattern on the top wiring layer, and forming a conductive pattern on the seed pattern.

According to some embodiments, the seed pattern may comprise at least one of copper, chromium, titanium, and titanium/tungsten, or the conductive pattern may comprise copper.

According to some embodiments, forming the shield vias may comprise forming directly on the first ground line.

According to some embodiments, the shield vias may be disposed spaced apart from one another according to a first spacing, and the first spacing may be greater than 0 and less than or equal to 500 μm.

According to some embodiments, forming a wiring layer below the uppermost wiring layer of the wiring layers may comprise forming a ground plane overlapping the first signal line, the second signal line, and the first ground line in a third direction substantially perpendicular to a top surface of the wiring substrate.

According to some embodiments, the bump pad structure and the shield structure may be simultaneously formed by the same electroplating process.

According to some embodiments, forming the shield line may be formed to extend along an extension direction of the first signal line and the second signal line.

According to some embodiments, forming the uppermost wiring layer may further comprise forming a second ground line spaced apart from the first ground line in the first direction with the first signal line interposed therebetween, and forming a third ground line spaced away from the first ground line in the first direction, with the second signal line interposed therebetween.

According to some embodiments, forming the first signal line may comprise forming a first sub signal line and a second sub signal line adjacent in the first direction, and forming the second signal line may comprise forming a third sub signal line and fourth sub signal line adjacent to one another in the first direction.

According to some embodiments, the first sub signal wire and the second sub signal line may transmit differential signals, and the third sub signal line and the fourth sub signal line may transmit differential signals.

A method of manufacturing a semiconductor package according to some embodiments may comprise forming a wiring substrate, forming the wiring substrate may comprise forming an insulating layer, and forming stacked wiring layers disposed within the insulating layer, and forming a bump pad structure and a shield structure on an uppermost wiring layer of the wiring layers, forming the uppermost wiring layer may comprise forming a first signal line, a second signal line, and a first ground line disposed therebetween, forming the bump pad structure may comprise forming a bump pad via and a bump pad on the bump pad via, forming the shield structure may comprise forming shield vias and a shield line on the shield vias, and forming the shield line may comprise forming at a same level as a level of the bump pad.

According to some embodiments, forming the shield vias may comprise forming at the same level as a level of the bump pad via.

According to some embodiments, forming the wiring substrate may further comprise forming a metal post structure on an uppermost wiring layer of the wiring layers, forming the metal post structure may comprise forming a post pad via, forming a post pad on the post pad via, and forming a metal post on the post pad, and forming the shield vias may comprise forming at a same level as a level of the post pad via.

According to some embodiments, forming the shield line may comprise forming on a top surface of the insulating layer.

A method of manufacturing a semiconductor package according to some embodiments may comprise forming a first redistribution substrate, mounting a semiconductor chip on the first redistribution substrate in a flip-chip manner, forming a mold layer covering a top surface of the first redistribution substrate and a top surface and a side surface of the semiconductor chip, and forming a second redistribution substrate on the mold layer, forming the first redistribution substrate comprises forming stacked wiring layers, and forming a bump pad structure and a shield structure on an uppermost wiring layer of the wiring layers, forming the uppermost wiring layer may comprise forming a first signal line, a second signal line, and a first ground line disposed therebetween, forming the shield structure may comprise forming shield vias and a shield line connected to the shield vias, and forming the shield line to be disposed between the first signal line and the second signal line in a plan view.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a wiring substrate comprising wiring layers and a shield structure,
wherein an uppermost wiring layer in the wiring layers comprises:
a first signal line and a second signal line spaced apart from one another along a first direction substantially parallel to a top surface of the wiring substrate; and
a first ground line disposed between the first signal line and the second signal line,
wherein the shield structure comprises:
shield vias on the first ground line; and
a shield line on the shield vias, and
wherein the shield line is disposed between the first signal line and the second signal line in a plan view.

2. The semiconductor package of claim 1, wherein:
the shield vias are arranged spaced apart from one another according to a first spacing, and
the first spacing is greater than 0 and less than or equal to 500 μm.

3. The semiconductor package of claim 1, wherein:
the first signal line, the second signal line, the first ground line, and the shield line are substantially parallel to a top surface of the wiring substrate and extend in a second direction substantially perpendicular to the first direction, and
the shield vias are disposed along the second direction.

4. The semiconductor package of claim 1, wherein the shield line overlaps with the first ground line in a third direction substantially perpendicular to the top surface of the wiring substrate.

5. The semiconductor package of claim 1,
wherein the uppermost wiring layer further comprises:
a second ground line spaced apart from the first ground line in the first direction with the first signal line interposed therebetween; and
a third ground line spaced apart from the first ground line in the first direction with the second signal line interposed therebetween.

6. The semiconductor package of claim 1, wherein:
the first signal line comprises a first sub signal line and a second sub signal line arranged adjacent to one another in the first direction, and
the second signal line comprises a third sub signal line and a fourth sub signal line disposed adjacent to one another in the first direction.

7. The semiconductor package of claim 6, wherein:
the first sub signal line and the second sub signal line transmit differential signals, and
the third sub signal line and the fourth sub signal line transmit differential signals.

8. The semiconductor package of claim 1, further comprising a semiconductor chip on the wiring substrate,
wherein, in a plan view, the shield structure is spaced apart from the semiconductor chip.

9. The semiconductor package of claim 8, wherein:
the wiring substrate comprises a first region on which the semiconductor chip is mounted, and a second region adjacent to the first region,
one end of the first signal line and one end of the second signal line are located at an edge of the first region,
the other end of the first signal line and the other end of the second signal line are located in the second region, and
the shield line extends from a boundary between the first region and the second region beyond the other end of the first signal line and the other end of the second signal line.

10. The semiconductor package of claim 1, wherein the shield line extends to a corner of the wiring substrate.

11. A semiconductor package comprising:
a wiring substrate comprising wiring layers, a shield structure, and a bump pad; and
a semiconductor chip on the wiring substrate,
wherein an uppermost wiring layer in the wiring layers comprises:
a first signal line and a second signal line spaced apart from one another along a first direction substantially parallel to a top surface of the wiring substrate; and
a ground line disposed between the first signal line and the second signal line,
wherein:
the bump pad and the shield structure are disposed on the uppermost wiring layer, and
the shield structure comprises:
shield vias on the ground line; and
a shield line on the shield vias,
the semiconductor chip comprises:
a chip pad; and
a connection terminal interposed between the chip pad and the bump pad, and
wherein the shield line is located at a same level as a level of the bump pad.

12. The semiconductor package of claim 11, wherein:
the wiring substrate further comprises a metal post structure, and
the semiconductor package further comprises an upper wiring substrate spaced apart from the wiring substrate in a third direction substantially perpendicular to a top surface of the wiring substrate with the semiconductor chip and the metal post structure interposed therebetween.

13. The semiconductor package of claim 12,
wherein the metal post structure comprises:
a post pad via on the uppermost wiring layer;
a post pad on the post pad via; and
a metal post on the post pad,
wherein the post pad is located at a same level as a level of the shield line and the bump pad.

14. The semiconductor package of claim 11,
wherein the shield structure comprises a seed pattern and a conductive pattern on the seed pattern.

15. The semiconductor package of claim 11, further comprising a mold layer covering a top surface of the wiring substrate, and a top surface and a side surface of the semiconductor chip, and
wherein a top surface and a side surface of the shield line are in contact with the mold layer.

16. A semiconductor package comprising:
a first semiconductor package,
wherein the first semiconductor package comprises:
a first wiring substrate comprising a first surface and a second surface opposite one another;
a semiconductor chip on the first surface of the first wiring substrate; and
first connection terminals on the second surface of the first wiring substrate,
wherein at least some of the first connection terminals are non-overlapping with the semiconductor chip,
wherein the semiconductor chip comprises a chip pad and a second connection terminal on the chip pad, the second connection terminal is disposed between the chip pad and the first wiring substrate,
wherein the first wiring substrate comprises wiring layers and a shield structure,
wherein the wiring layers comprise a first wiring layer and a second wiring layer disposed below the first wiring layer,
wherein the first wiring layer located at an uppermost one of the wiring layers comprises a first signal line, a second signal line, which are spaced apart from one another along a first direction substantially parallel to a top surface of the first wiring substrate, and a ground line disposed between the first signal line and the second signal line,
wherein:
the second wiring layer comprises a ground plane overlapping with the first signal line, the second signal line, and the ground line, and
the shield structure comprises:
shield vias on the ground line; and
a shield line on the shield vias.

17. The semiconductor package of claim 16, wherein the first wiring substrate is a redistribution substrate or a printed circuit board.

18. The semiconductor package of claim 16, wherein:
the first wiring substrate further comprises an insulating layer,
the first signal line, the second signal line, the ground line, the shield via, and the ground plane are disposed in the insulating layer, and
the shield line is disposed on the insulating layer.

19. The semiconductor package of claim 16, wherein:
the first wiring substrate further comprises a metal post disposed on a top surface of the first wiring substrate and spaced apart from the semiconductor chip in a second direction substantially parallel to the top surface of the second wiring substrate and substantially perpendicular to the first direction,
the first semiconductor package further comprises a second wiring substrate on the semiconductor chip and the metal post, and
the semiconductor package further comprises a second semiconductor package on the first semiconductor package.

20. The semiconductor package of claim 16, wherein a width of the shield line in the first direction is smaller than a width of the ground plane in the first direction.
